(19) United States
(12) Patent Application Publication
(10) Pub. No.: US 2011/0097822 A1
(43) Pub. Date: Apr. 28, 2011

(54) FABRICATION METHOD OF SEMICONDUCTOR DEVICE WITH UNIFORM TOPOLOGY

(75) Inventor: Min Yong LEE, Gyeonggi-do (KR)

(73) Assignee: HYNIX SEMICONDUCTOR INC., Gyeonggi-do (KR)

(21) Appl. No.: 12/649,048

(22) Filed: Dec. 29, 2009

(30) Foreign Application Priority Data
Oct. 22, 2009 (KR) 10-2009-0100858

(51) Int. Cl. H01L 21/66

(52) U.S. Cl. 438/5; 257/E21.53

(57) ABSTRACT

A method of manufacturing a semiconductor device to have uniform topology includes forming an interlayer insulating layer on a semiconductor device, carrying out an ion implantation process by varying an amount of ion-implantation according to a height profile of the interlayer insulating layer, and planarizing the interlayer insulating layer.

### CROSS-REFERENCES TO RELATED APPLICATION

The present application claims priority under 35 U.S.C. 119(a) to Korean application number 10-2009-0100858, filed on Oct. 22, 2009, in the Korean Patent Office, which is incorporated by reference in its entirety as if set forth in full.

### BACKGROUND

1. Technical Field

The embodiments described herein relate generally to a method of manufacturing a semiconductor device and, more particularly to a method of manufacturing a semiconductor device with a uniform topology.

2. Related Art

Recently, a high integration semiconductor memory device is being fabricated of a switching device, such as a diode, and a transistor formed in a vertical structure. In particular, in a flash memory device, for example a phase change memory device, a vertical type switching device.

When a vertical type switching device is utilized, the height of an interlayer insulating layer for isolation between switching devices is increased. Since the interlayer insulating layer is formed to have a height higher than the determined height over a wide area, it can be formed to have an irregular height. Accordingly, electrical characteristics, such as an operation current of the switching diode to be formed in the following process, become non-uniform, and as a result, the reliability of a semiconductor device is deteriorated.

FIGS. 1 to 3 are cross-sectional views shown for illustrating a conventional method of manufacturing a semiconductor device. As shown in FIG. 1, an interlayer insulating layer 12 is formed on a semiconductor device 10 having an understructure formed therein.

As a result of the forming of the interlayer insulating layer 12 having a high height over a wide area, the interlayer insulating layer 12 is formed to have a height at an edge portion of a wafer (i.e., the semiconductor substrate 10) which is greater than the height at a center portion of the semiconductor substrate 10. This phenomenon is called as WiW (within wafer uniformity) variation, and in FIG. 1, WiW variation is generated having a difference in height ΔD between the edge portion and the center portion of the wafer.

As shown in FIG. 2, a predetermined portion of the interlayer insulating layer 12 is patterned to form holes exposing a surface of the semiconductor substrate 10. Next, as shown in FIG. 3, a selective epitaxial growth (SEG) layer 14, which is to be used as a switching device, is formed within the holes.

It is understood that a height of the SEG layer 14 is also non-uniform due to the step difference ΔD of the interlayer insulating layer 12. That is, the height D2 of the SEG layer 14 formed in the center portion of the semiconductor substrate 10 is less than that of the height of the SEG layer formed in the edge portion of the semiconductor substrate 10. Accordingly, the electric characteristic of the SEG layer 14 is different depending on the position of the SEG layer 14 formed in the semiconductor substrate 10 such that the operation characteristic of the device is deteriorated and the reliability of the device cannot be satisfactorily maintained.

FIGS. 4A to 4C are cross-sectional views shown for illustrating exemplary profiles of step differences in the interlayer insulating layer resulting from a conventional fabrication method of the semiconductor device. As shown if FIG. 4A, the interlayer insulating layer 12 is formed on the semiconductor substrate 10 to have a step difference in which a center portion of the interlayer insulating layer 12 has a greater height than an edge portion of the interlayer insulating layer 12, that is, the interlayer insulating layer 12 has a “n” type profile. As shown in FIG. 4B, the interlayer insulating layer 12 may be formed in a “W” type profile, or as shown in FIG. 4C, the interlayer insulating layer 12 may be formed in an “M” type profile.

Although the interlayer insulating layer 12 having various WiW step differences, as described above, can be planarized through a subsequent CMP process, the interlayer insulating layer 12 tends to follow the initial deposition profile after the CMP process, it is difficult to completely planarize the interlayer insulating layer 12. Further, the problem still remains even through any pattern is formed under the interlayer insulating layer 12.

In order to solve the problem, a planarization method carried out under different pressures according to the deposition profile of the layer to be planarized has been suggested. In particular, a portion of the interlayer insulating layer having a higher height may be planarized by increasing an amount of polishing under a high pressure. However, when CMP is carried out by varying the pressure according to the height, it gives rise to produce the side effects that an amount of polishing is relatively reduced in portions peripheral to the portions which is polished by increased pressure.

In addition, when the CMP is carried out in a portion having a larger WiW variation under a high pressure, the wafer is damaged and a sliding out phenomenon where a wafer is deviated from the chuck may occur. Accordingly, there exists a demand for a method to eliminate the step difference of the interlayer insulating layer without physically impacting or damaging the wafer.

### SUMMARY

Embodiments of the present invention include a method of manufacturing a semiconductor device with a uniform topology by forming an interlayer insulating layer with a uniform height.

Embodiments of the present invention include a method of manufacturing a semiconductor device with a uniform topology being capable of ensuring a uniform operation characteristic of a vertical switching device.

In one embodiment, a method of manufacturing a semiconductor device with a uniform topology includes forming an interlayer insulating layer on a semiconductor device; carrying out an ion implantation process by varying an amount of ion-implantation according to a height profile of the interlayer insulating layer; and planarizing the interlayer insulating layer.

These and other features, aspects, and embodiments are described below in the section entitled “DETAILED DESCRIPTION.”

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIGS. 1 through 3 are sectional views illustrating a conventional method of manufacturing a semiconductor device;

FIGS. 4A through 4C are sectional views explaining profiles of step difference in an interlayer insulating layer in the conventional fabrication method of the conventional semiconductor device;

FIGS. 5 through 9 are sectional views illustrating a method of manufacturing a semiconductor device according to an exemplary embodiment;

FIG. 10 is a plan view of the semiconductor device of FIG. 6.

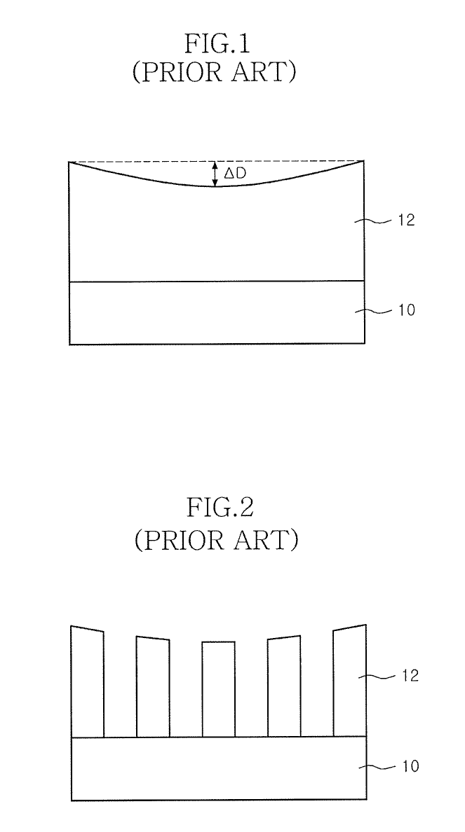

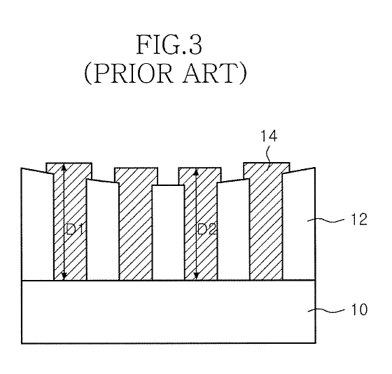

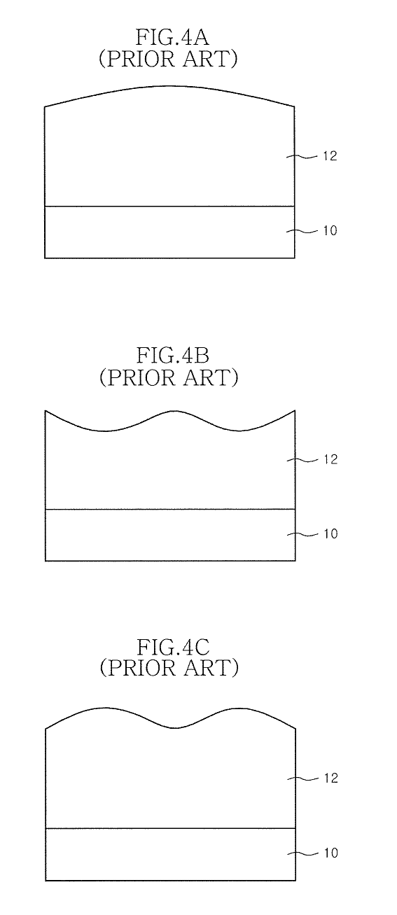

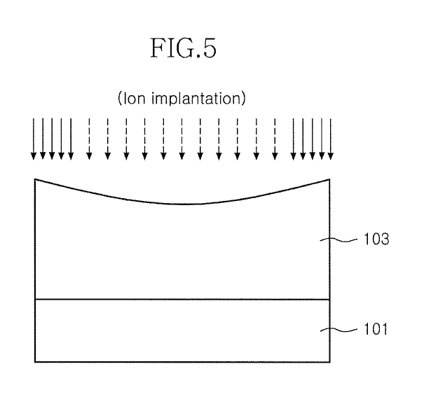

### DETAILED DESCRIPTION

Hereinafter, embodiments of the present invention will be described in detail with reference to the attached drawings. The present invention may, however, be modified in many different forms and should not be constructed as being limited to the embodiments set forth herein. Rather, these embodiments are provided so that this disclosure will be through and complete, and will be fully convey the inventive concepts to one of ordinary skill in the art. In the drawings, shapes of the elements, etc. may be exaggerated for clarity. Like reference numerals in the drawings denote like elements. It is also understood that when a layer is referred to as being “on” another layer or substrate, it can be directly on the other or substrate, or intervening layers may also be present.

FIGS. 5 to 9 are cross-sectional views shown for illustrating a method of manufacturing a semiconductor device according to an exemplary embodiment of the present invention.

First, referring to FIG. 5, an interlayer insulating layer 103 is formed on a semiconductor substrate 100. The interlayer insulating layer 103 is formed over a wide area at a height in the range of 5000 to 6000 Å, or more, such that a step difference in the range of 300 to 400 Å may be formed between a portion of a high height and a portion of a low height in the interlayer insulating layer 103. A profile representing WiW deviation may be in a U-shape, an n-shape, a W-shape an M-shape, or the like. For example, a U-shape step difference generated in the interlayer insulating layer 103 is shown in FIG. 5.

According to an embodiment of the present invention, a planarization process is carried out so as solve the step difference. According to an embodiment of the present invention, the planarization process is carried out under the same pressure, and an ion implantation process is carried out through a locally differential self ion implantation (LDSI) method, so as to increase an amount of polishing in a portion of the interlayer insulating layer having a high height.

The LDSI method is an ion implantation method which controls an amount of ion-implantation according to a moving speed of the semiconductor substrate. The ion implantation process is carried out by moving the semiconductor substrate, reducing the moving speed of the semiconductor substrate in the portion of the semiconductor substrate in which a high concentration impurity is to be ion-implanted in, and increasing the moving speed of the semiconductor substrate in the portion of the semiconductor substrate in which a low concentration impurity is to be ion-implanted, such that the ion implantation concentration is differentially adopted depending on the position of the semiconductor substrate. Accordingly, in an exemplary embodiment, after the interlayer insulating layer 103 is formed, a profile of the interlayer insulating layer 103 is analyzed and then the amount of ion implantation is determined according to the profile and a material of the interlayer insulating layer 103.

For example, when the interlayer insulating layer 103 is comprised of High Density Plasma (HDP) oxide or Tetra Ethyl Ortho Silicate (TEOS), an amount of ion-implantation in the portion of a relatively higher height may be increased in the range of 20 to 600% as compared with an amount of ion implantation in the portion of a lower height. According to embodiments of the present invention, the implanting ion may be at least one of any of the elements usable in the ion implantation process, and for example one or more of the elements comprising Si, N, Ge, and Ar. In addition, an ion implantation energy may be in the range of 1 eV to 100 keV.

When the interlayer insulating layer 103 is comprised of Boro-Phospho Silicate Glass (BPSG), an amount of ion-implantation in the portion of a relatively higher height may be increased in the range of 1 to 150% as compared with an amount of ion implantation in the portion of a lower height. According to embodiments of the present invention, the implanting ion may be at least one of any of the elements usable in the ion implantation process, and for example, one or more of P or B. In addition, an ion implantation energy may be in the range of 1 eV to 100 keV.

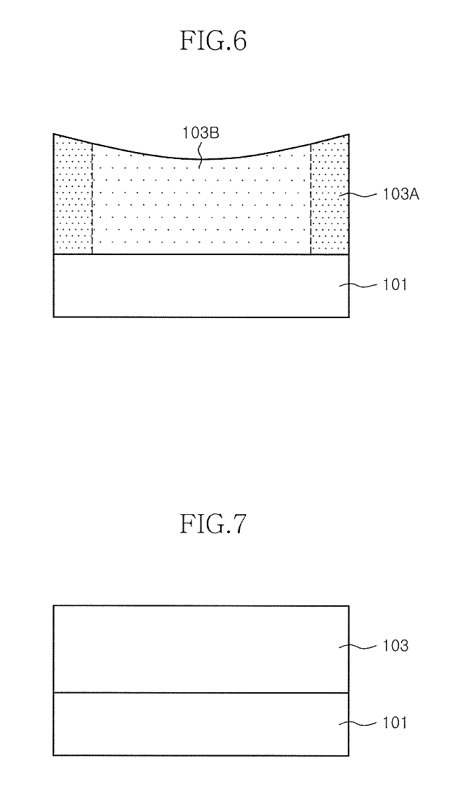

As shown in FIG. 6, shows the resultant state of the completed ion implantation process to the interlayer insulating layer 103. It is understood that a higher concentration impurity is implanted in the portion 103A of a relatively higher height in the interlayer insulating layer 103 and a lower concentration impurity is implanted in the portion 103B of a relative lower height.

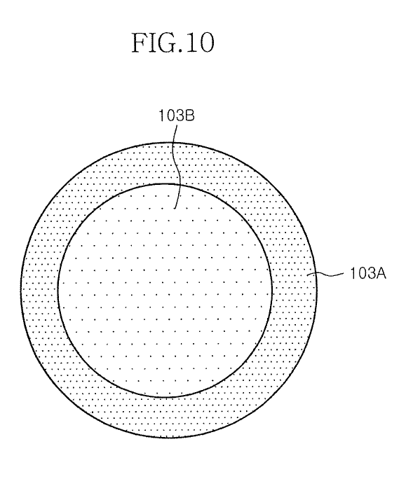

FIG. 10 shows a plan view of FIG. 6. It is understood that an large amount of ions are implanted into the edge portion 103A, that is, the portion 103A having a higher topology, and a lesser amount of ions by contrast are implanted into the center portion 103B, that is, the portion 103B having a lower topology.

After carrying out the ion implantation process, referring to FIG. 7, a planarization process is carried out. The planarization process may be carried out through a CMP process, and the step difference between the edge portion and the center portion can be solved by increasing an amount of polishing in the high concentration impurity-implanted region and by reducing an amount of polishing in the low concentration impurity-implanted region.

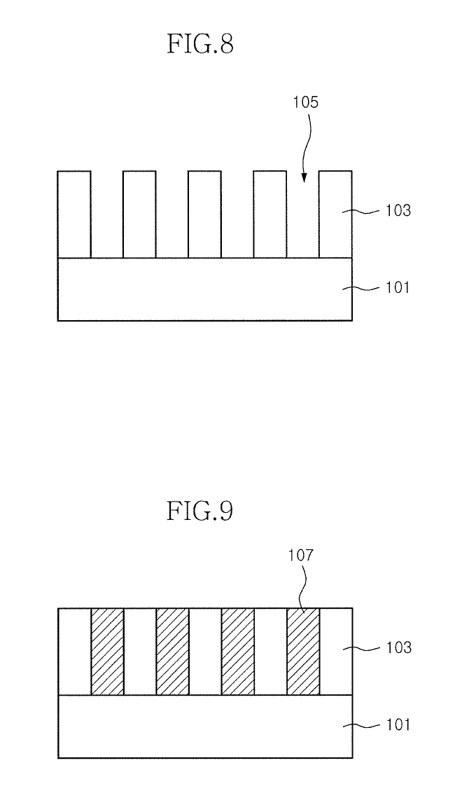

Subsequently, Referring to FIG. 8, a portion of the interlayer insulating layer 103 which is a switching device formation region is patterned to define holes 105. Referring to FIG. 9, a SEG layer 107 is formed within the holes 105. Since the interlayer insulating layer 103 is formed at a uniform height, the SEG layer 107 formed within the holes 105 of the interlayer insulating layer 103 is also formed at a uniform height. Accordingly, when a switching diode is formed by implanting ions in the SEG layer 107 in a subsequent process, a uniform electrical characteristic of the switching diode can be maintained.

According to embodiments of the present invention, an amount of ion-implantation is varied according to a height profile of an interlayer insulating layer. Accordingly, even though the CMP is carried out for the entire interlayer insulating layer under the same pressure, an amount of polishing in high concentration impurity-implanted region can be increased so as to solve the step difference in the interlayer insulating layer.

While certain embodiments have been described above, it will be understood that the embodiments described are by way of example only. Accordingly, the devices and methods described herein should not be limited based on the described embodiments. Rather, the devices and methods described herein should only be limited in light of the claims that follow when taken in conjunction with the above description and accompanying drawings.

What is claimed is:

1. A method of manufacturing a semiconductor device with a uniform topology, comprising:
forming an interlayer insulating layer on a semiconductor substrate;
carrying out an ion implantation process on the interlayer insulating layer, an amount of the ion-implantation varied according to a height profile of the interlayer insulating layer; and
planarizing the interlayer insulating layer.

2. The method of claim 1, wherein the carrying out an ion implantation process comprises ion implanting a high concentration impurity in a portion of the interlayer insulating layer having a high height as compared with a portion of the interlayer insulating layer having a low height.

3. The method of claim 1, wherein the carrying out an ion implantation process comprises:
analyzing the height profile of the interlayer insulating layer;
determining the amount of ion-implantation according to a height and a material of the interlayer insulating layer; and
ion implanting ions into the interlayer insulating layer by reducing a moving speed of the semiconductor substrate in a portion of the interlayer insulating layer having a high height and increasing the moving speed of the semiconductor substrate in a portion of the interlayer insulating layer having a low height as compared with the low light.

4. The method of claim 1, wherein the interlayer insulating layer is formed at a height in the range of 5000 to 6000 Å.

5. The method of claim 4, wherein the interlayer insulating layer comprises one of a High Density Plasma (HDP) and a Tetra Ethyl Ortho Silicate (TEOS),
wherein the ion implantation process is carried out by increasing the amount of ion-implantation in the portion of the interlayer insulating layer having the high height in the range of 20 to 600% as compared with the portion of the interlayer insulating layer having the low height.

6. The method of claim 5, wherein the ion implantation process is carried out by using an element selected from the group consisting of Si, N, Ge and Ar.

7. The method of claim 6, wherein the ion implantation process is carried out at energy in the range of 1 eV to 100 KeV.

8. The method of claim 4, wherein the interlayer insulating layer comprises Boro-Phospho Silicate Glass (BPSG),
wherein the ion implantation process is carried out by increasing the amount of ion-implantation in the portion of the interlayer insulating layer having the high height in the range of 1 to 150% as compared with the portion of the interlayer insulating layer having the low height.

9. The method of claim 8, wherein the ion implantation process is carried out by using an element selected from the group consisting of B and P.

10. The method of claim 9, wherein the ion implantation process is carried out at energy in the range of 1 eV to 100 KeV.
